(19) United States
(12) Patent Application Publication
(10) Pub. No.: US 2008/0111186 A1
(43) Pub. Date: May 15, 2008

(54) Field-Effect Transistor Structure and Method Therefor

(75) Inventor: Petar Atanackovic, Palo Alto, CA (US)

Correspondence Address: DEMONT & BREYER, LLC, 100 COMMONS WAY, Ste. 250, HOLMDEL, NJ, 07733, US

(73) Assignee: TRANSLUCENT PHOTONICS, INC., Palo Alto, CA (US)

(21) Appl. No.: 11/559,681

(22) Filed: Nov. 14, 2006

(51) Int. Cl. H01L 29/786; H01L 21/782

(52) U.S. Cl. 257/347; 438/151; 257/E29.273; 257/E21.7

(57) ABSTRACT

A transistor structure comprising a single-crystal gate conductor disposed on a single-phase high-K dielectric gate dielectric is disclosed. The transistor structure is particularly suitable for fully-depleted silicon-on-insulator electronics.

### CROSS REFERENCE TO RELATED APPLICATIONS

The underlying concepts, but not necessarily the language, of the following cases are incorporated by reference:

(1) U.S. patent application Ser. No. 11/253,525, filed 19 Oct. 2005; and

(2) U.S. patent application Ser. No. 11/254,031, filed 19 Oct. 2005.

If there are any contradictions or inconsistencies in language between this application and one or more of the cases that have been incorporated by reference that might affect the interpretation of the claims in this case, the claims in this case should be interpreted to be consistent with the language in this case.

### FIELD OF THE INVENTION

The present invention relates to integrated circuits in general, and, more particularly, to field-effect transistors.

### BACKGROUND OF THE INVENTION

Many modern integrated circuits are complicated arrangements of millions of individual elements called Metal-Oxide-Semiconductor Field-Effect Transistors (“MOSFETs”). The remarkable decades-long progression in the performance of state-of-the-art electronics has been enabled by steadily shrinking the size of these transistors. The desired pace of MOSFET device scaling has the gate-length (i.e., size) of transistors shrinking to less than 100 nanometers (nm). But achieving this size scale is problematic. In particular, for transistors formed using conventional bulk silicon substrates, performance begins to suffer when gate length is reduced to less than 100 nm. At this size scale, substrate effects and physical limitations associated with silicon dioxide gate dielectric material become severe.

To meet this challenge, new material systems are being considered. Three technologies that have attracted the interest of researchers are:

Partially-depleted silicon-on-insulator technology;

High-K dielectric materials; and

Fully-depleted silicon-on-insulator technology.

### These technologies, and their limitations, are discussed in some detail below.

Partially-depleted silicon-on-insulator (PD-SOI) technology was introduced to overcome some of the limitations on transistor scaling associated with the use of a bulk silicon wafer. An SOI substrate suitable for PD-SOI comprises a silicon active layer that is separated from a bulk silicon handle wafer by a buried silicon dioxide layer. The silicon active layer has a thickness that is typically greater than 200 nm. As for conventional MOSFETs, in order to activate a PD-SOI transistor, a voltage is applied to a gate. The gate itself is formed of an electrically-conductive polysilicon layer (i.e., the gate conductor) that is disposed on a silicon dioxide layer (i.e., the gate dielectric). The gate dielectric electrically isolates the gate conductor from the active layer, thus forming a capacitor structure.

The gate voltage creates an electric field under the gate, which drives away existing charge carriers in the active layer under the gate (referred to as the “channel”). This creates a carrier “depletion region” in the channel. The depletion region extends through only a portion of the thickness of the active layer (i.e., the active layer is “partially-depleted”). For a sufficiently high gate voltage (i.e., greater than a “threshold voltage”), a carrier “inversion” occurs and the channel becomes highly electrically-conductive. This allows electrical current to flow between source and drain regions, which are located at either end of the channel.

PD-SOI alleviates some of the physical limitations inherent to transistors that are made using bulk silicon substrates. As the gate-length of the transistors is reduced to less than 65 nm, however, PD-SOI transistors begin to exhibit increased short channel effects and poor on/off current ratios. The 65 nm transistor technology node, therefore, represents a potential limit for PD-SOI.

The drive toward shorter gate-length transistors has forced the aggressive scaling of the gate oxide thickness to below 2 nm. Unfortunately, in this thickness regime, silicon dioxide is subject to direct electron tunneling and can exhibit significant leakage current (greater than 10 Amps/cm²). This leads to high sub-threshold currents, high switching currents, and, therefore, high power dissipation.

Alternative gate dielectric materials, therefore, are being aggressively pursued. For example, materials that have a relatively high dielectric constant—so called “high-K dielectrics”—might provide some advantage as a gate dielectric. Examples of high-K dielectrics include hafnium oxide and silicon oxynitride. To the extent that these materials have a higher dielectric constant than silicon dioxide, the same operational characteristics as thin silicon dioxides can be derived with thicker high-K dielectric layers. Alternatively, thin high-K gate dielectrics used in place of thin silicon dioxide gate dielectrics allow transistor operation at lower gate voltage, thereby reducing leakage current, etc. To date, however, material quality, morphology issues, and poor interface quality have limited the benefits of high-K dielectric materials vis-a-vis their use as gate dielectrics.

Carrier tunneling through thin silicon dioxide gate dielectrics can also arise from dopant penetration through the oxide and into the channel during fabrication. In conventional SOI-based transistors, the polysilicon gate conductor is doped (typically with boron) in order to make it sufficiently conductive. During fabrication, the boron must be activated by means of a high-temperature anneal. At elevated temperatures, the diffusivity of boron along the grain boundaries of the polysilicon, and through silicon dioxide, is quite high. As a consequence, when subjected to the elevated annealing temperatures, boron can poison the transistors.

The thick buried oxide layer (BOX) typical of conventional SOI substrates also contributes to several undesirable device issues. First, silicon dioxide is a poor thermal conductor. A thick silicon dioxide layer, therefore, is an impediment to the efficient conduction of heat generated by the dense arrays of transistors of modern electrical circuits.

Second, a thick BOX (typically 100-400 nm) leads to deleterious electric-field fringing, which exacerbates undesirable short-channel effects. This acts to further increase sub-threshold currents in the transistors.

Third, transistors formed on SOI substrates having thick BOX layers have been shown to exhibit a larger variation of threshold voltage (i.e., the turn-on voltage of a transistor) and leakage current.

Fully-depleted SOI (FD-SOI) represents an attractive alternative below the 65 nm technology node. In an FD-SOI substrate, the active layer is made extremely thin (typically <70 nm) compared to the active layer of PD-SOI substrate. As a result, in an activated FD-SOI transistor, the depletion region extends through the entire thickness of the active layer (i.e., the active layer is “fully-depleted”).

In addition to the active layer, it is also desirable that the gate dielectric and buried dielectric layers be made much thinner for FD-SOI than for PD-SOI. Conventional SOI substrate fabrication technologies, however, are ill-suited to the production of SOI substrates having thin, uniform-thickness active layers and buried dielectric layers. Currently-available methods to produce SOI wafers rely on wafer bonding of oxidized silicon wafers followed by removal of most of one of the two substrates to form the active layer. Although several variations of this technology exist, all are incapable of providing ultra-thin active layers of sufficient quality for fully-depleted electronics. The active layer of conventional SOI substrates is limited to a thickness within the range of about 50 nm to about 150 nm and buried dielectric layer is limited to a thickness within the range of about 50 nm to about 400 nm. In addition, the uniformity of these layers is optimistically expected to be approximately ±10 nm. Also, the interface quality and impurity concentration of conventional buried oxide layers is insufficient to support high-performance integrated circuitry. Finally, the complexity of wafer bonding processes used to produce SOI wafers is quite high, which leads to high costs. For these reasons, among any others, the acceptance of SOI wafers by the semiconductor industry has been rather limited.

A transistor technology that mitigates at least some of the costs and disadvantages of the prior-art, therefore, would be a significant advance in the state-of-the-art in microelectronics.

### SUMMARY OF THE INVENTION

The present invention provides a composition comprising a single-crystal semiconductor disposed on a single-phase high-K dielectric layer. This composition is suitable for use in FD-SOI or PD-SOI transistor structures as: (1) the gate conductor and gate dielectric of FETs; and/or (2) a semiconductor active layer disposed on a high-K buried dielectric layer. The composition provides particular advantages for transistors having gate lengths at or below 65 nm. As described in detail later in this specification, single-phase morphology is characterized by a single-crystal, single-domain crystalline structure. The dielectrics and active layer are deposited via an epitaxy process.

A distinguishing feature of the compositions disclosed herein is the morphology of the rare-earth dielectric and the morphology of the semiconductor. In particular, the rare-earth dielectric exhibits single-phase morphology and the semiconductor exhibits single-crystal morphology. In some embodiments, both the rare-earth dielectric and the semiconductor exhibit single-phase morphology. The single-crystal (or single-phase) morphology of the semiconductor is, in fact, enabled by single-phase morphology of the underlying rare-earth dielectric layer.

A single-crystal semiconductor gate layer disposed on a single-phase gate dielectric layer composes a structure that provides improved immunity to the well-known problem of boron-poisoning in the gate dielectric. In the prior-art, the gate conductor typically comprises boron-doped polysilicon, which is formed on a silicon-dioxide gate oxide. A high-temperature anneal is required to activate the boron to make the polysilicon ohmic. During this anneal, boron readily diffuses along grain boundaries in the polysilicon and into the amorphous silicon dioxide. In the present invention, the single-crystalline nature of the semiconductor gate layer and gate dielectric reduces the diffusivity of the boron by up to four orders of magnitude as compared to polysilicon.

Some embodiments of the present invention comprise a single-crystal semiconductor gate disposed on a single-phase rare-earth gate dielectric disposed on a single-phase semiconductor active layer disposed on a single-phase rare-earth buried dielectric layer disposed on a substrate.

In some embodiments, the composition is analogous to a FD-SOI (or PD-SOI) wafer in the prior art; wherein (1) the rare-earth buried dielectric layer serves as the buried oxide layer (BOX); (2) the semiconductor active layer serves as the upper, active layer of silicon; (3) the rare-earth gate dielectric layer serves as the thin gate oxide layer; and (4) the semiconductor gate serves as the polysilicon gate.

In contrast to FD-SOI and PD-SOI structures based on SOI, known in the prior-art, the gate dielectric and gate conductor disclosed herein enable FETs having:
i. high-K dielectric constant; or
ii. higher carrier mobility transistors based on germanium or silicon-germanium active layers; or
iii. lower sub-threshold leakage current; or
iv. lower power dissipation circuitry; or
v. mitigated short-channel effects; or
vi. mitigated floating-body effects; or
vii. higher transistor drive current; or
viii. thinner buried dielectric layers; or
ix. any combination of i, ii, iii, iv, v, and vi, vii, and viii.

The presence of single-phase materials in the compositions disclosed herein results in high-quality dielectric/semiconductor interfaces, such as are required for high-performance devices and circuits. Furthermore, rare-earth dielectric layers that exhibit single-phase morphology, as disclosed herein, do not suffer from either an upper or lower limitation on thickness, as are exhibited in the prior art.

In some embodiments, compositions disclosed herein comprise active layers that are as thin as a few nanometers, yet which retain single-phase morphology and high-quality interfaces. Active layers such as these, coupled with a high-quality high-K dielectric gate and buried dielectric layer, enable the formation of FD-SOI transistors with mitigated short-channel effects, improved transistor operation, more robust electrical circuits due to mitigated floating body effects.

### BRIEF DESCRIPTION OF THE DRAWINGS

FIG. 1 depicts a cross-sectional view of a transistor structure in accordance with an illustrative embodiment of the present invention.

FIG. 2 depicts the crystal structure diagram of a unit cell of a rare-earth oxide having the formula RE₂O₃ in accordance with the illustrative embodiment of the present invention.

FIG. 3 depicts a chart of the polymorphs of rare-earth oxides versus temperature and as a function of cation radius.

FIG. 4A depicts a cross-sectional view of a portion of a semiconductor-on-insulator substrate comprising a buried ground plane in accordance with an alternative embodiment of the present invention.

FIG. 4B depicts a cross-sectional view of a portion of a semiconductor-on-insulator substrate comprising a buried conductor in accordance with an alternative embodiment of the present invention.

FIG. 4C depicts a cross-sectional view of a portion of a semiconductor-on-insulator substrate comprising a buried conductor layer and a buried ground plane in accordance with an alternative embodiment of the present invention.

FIG. 5A depicts a cross-sectional view of a portion of a semiconductor-on-insulator substrate comprising a buried dielectric layer having an oxygen concentration gradient, before anneal, in accordance with an alternative embodiment of the present invention.

FIG. 5B depicts a cross-sectional view of a portion of a semiconductor-on-insulator substrate comprising a buried dielectric layer having a reduced high-K dielectric constant, after anneal, in accordance with an alternative embodiment of the present invention.

FIG. 6 depicts a method for forming a transistor in accordance with the illustrative embodiment of the present invention.

FIG. 7 depicts a method for forming a composite buried dielectric layer having a reduced dielectric constant in accordance with an alternative embodiment of the present invention.

### DETAILED DESCRIPTION

The following terms are defined for use in this Specification, including the appended claims:
Layer means a substantially-uniform thickness of a material covering a surface. A layer can be either continuous or discontinuous (i.e., having gaps between regions of the material). For example, a layer can completely cover a surface, or be segmented into discrete regions, which collectively define the layer (i.e., regions formed using selective-area epitaxy).
Disposed on means “exists on” an underlying material or layer. This layer may comprise intermediate layers, such as transitional layers, necessary to ensure a suitable surface. For example, if a material is described to be “disposed on a substrate,” this can mean either (1) the material is in intimate contact with the substrate; or (2) the material is in contact with one or more transitional layers that reside on the substrate.
Single-crystal means a crystalline structure that comprises substantially only one type of unit-cell. A single-crystal layer, however, may exhibit some crystalline defects such as stacking faults, dislocations, or other commonly occurring crystalline defects.
Single-domain means a crystalline structure that comprises substantially only one structure of unit-cell and substantially only one orientation of that unit cell. In other words, a single-domain crystal is a single-crystal crystalline structure that exhibits no twinning or anti-phase domains.
Single-phase means a crystalline structure that is both single-crystal and single-domain.
Substrate means the material on which deposited layers are formed. Exemplary substrates include, without limitation: bulk silicon wafers, in which a wafer comprises a homogeneous thickness of single-crystal silicon; composite wafers, such as a silicon-on-insulator wafer that comprises a layer of silicon that is disposed on a layer of silicon dioxide that is disposed on a bulk silicon handle wafer; or any other material that serves as base layer upon which, or in which, devices are formed. Examples of such other materials that are suitable, as a function of the application, for use as substrate layers and bulk substrates include, without limitation, germanium, alumina, gallium-arsenide, indium-phosphide, silica, silicon dioxide, borosilicate glass, Pyrex, and sapphire.
Miscut Substrate means a substrate which comprises a surface crystal structure that is oriented at an angle to that associated with the crystal structure of the substrate. For example, a 6° miscut <100> silicon wafer comprises a <100> silicon wafer that has been cut at an angle to the <100> crystal orientation by 6° toward another major crystalline orientation, such as <110>. Typically, but not necessarily, the miscut will be up to about 20 degrees. Unless specifically noted, the phrase “miscut substrate” includes miscut wafers having any major crystal orientation. That is, a <111> wafer miscut toward the <011> direction, a <100> wafer miscut toward the <110> direction, and a <011> wafer miscut toward the <001> direction.

Semiconductor-on-Insulator means a composition that comprises a single-crystal semiconductor layer, a single-phase dielectric layer, and a substrate, wherein the dielectric layer is interposed between the semiconductor layer and the substrate. This structure is reminiscent of prior-art silicon-on-insulator (“SOI”) compositions, which typically include a single-crystal silicon substrate, a non-single-phase dielectric layer (e.g., amorphous silicon dioxide, etc.) and a single-crystal silicon semiconductor layer. Several important distinctions betweens prior-art SOI wafers and the inventive semiconductor-on-insulator compositions are that:
Semiconductor-on-insulator compositions include a dielectric layer that has a single-phase morphology, whereas SOI wafers do not. In fact, the insulator layer of typical SOI wafers is not even single crystal.
Semiconductor-on-insulator compositions include a silicon, germanium, or silicon-germanium “active” layer, whereas prior-art SOI wafers use a silicon active layer. In other words, exemplary semiconductor-on-insulator compositions in accordance with the invention include, without limitation: silicon-on-insulator, germanium-on-insulator, and silicon-germanium-on-insulator.

In some embodiments, the semiconductor-on-insulator compositions that are disclosed herein include additional layers between the semiconductor layer and the substrate.

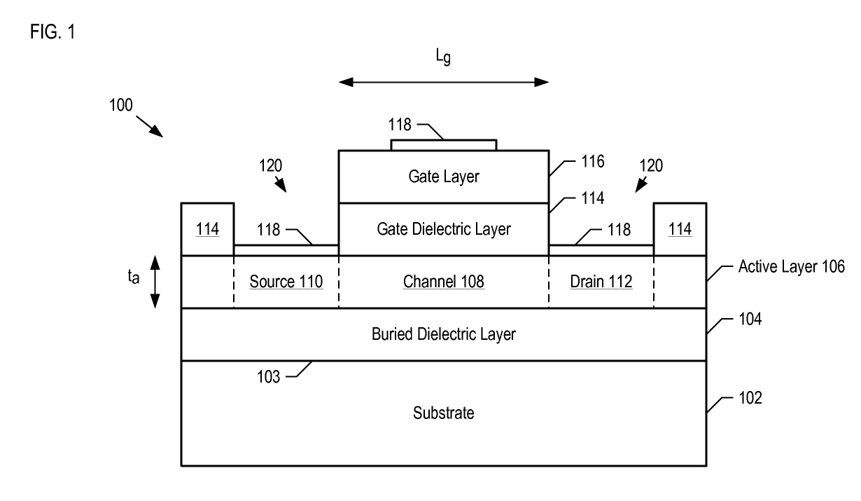

FIG. 1 depicts a cross-sectional view of a transistor structure in accordance with an illustrative embodiment of the present invention. Transistor 100 comprises substrate 102, buried dielectric layer 104, active layer 106, gate dielectric layer 114, gate layer 116, and electrical contacts 118. Transistor 100 is a single-gate planar transistor formed in a semiconductor-on-insulator structure. The crystal structure of each of the dielectric and semiconductor layers that compose the semiconductor-on-insulator structure is either single-phase or single-crystal. Each of the layers, with the exception of the electrical contacts, is deposited using atomic-layer epitaxy, as described in U.S. patent application Ser. No. 11/254,031.

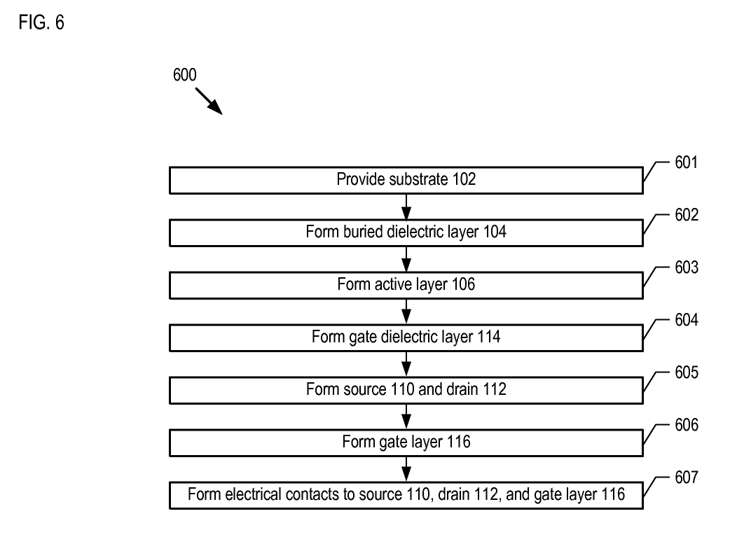

With reference to FIGS. 1 and 6, the structure of transistor 100 is described here in conjunction with method 600, which is suitable for the fabrication of transistor 100.

Method 600 begins with operation 601, in which substrate 102 is provided. Substrate 102 is a mis-cut silicon wafer. Substrate 102 has a predominantly <100> crystal orientation, but is mis-cut such that the orientation of surface 103 is at an angle to the <100> crystal orientation by 6° toward the <110> crystal orientation. Surface 103, therefore, supports the formation of a rare-earth dielectric layer having a single-phase crystal structure. Although surface 103 is mis-cut by 6° toward the <110> crystal orientation, it will be clear to those skilled in the art, after reading this specification, how to make and use alternative embodiments of the present invention wherein surface 103 is otherwise modified to support the formation of a rare-earth dielectric layer having a single-phase crystal orientation. In some alternative embodiments, substrate 102 is a wafer other than <100> silicon. Other suitable substrate materials include, without limitation, <111> silicon, <011> silicon, <100> silicon, miscut <111> silicon, miscut <011> silicon, germanium, and miscut germanium.

At operation 602, buried dielectric layer 104 is formed on surface 103 of substrate 102. Buried dielectric layer 104 is a layer of erbium oxide having a thickness of approximately 10 nanometers (nm). Buried dielectric layer 104 is epitaxially-grown on and monolithically-integrated with substrate 102. Among any other purposes, buried dielectric layer 104 provides a high-K dielectric layer that electrically isolates active layer 106 from substrate 102. Although in the illustrative embodiment buried dielectric layer 104 comprises erbium oxide, it will be clear to those skilled in the art, after reading this specification, how to make and use alternative embodiments of the present invention wherein buried dielectric layer 104 comprises a different rare-earth dielectric. Additional materials suitable for use as buried dielectric layer 104 include, without limitation:
i. other rare-earth oxides, such as oxides of ytterbium, dysprosium, holmium, thulium, and lutetium; or
ii. rare-earth nitrides, such as nitrides of erbium, ytterbium, dysprosium, holmium, thulium, and lutetium; or
iii. rare-earth phosphides, such as phosphides of erbium, ytterbium, dysprosium, holmium, thulium, and lutetium; or
iv. rare-earth oxynitrides, such as oxynitrides of erbium, ytterbium, dysprosium, holmium, thulium, and lutetium; or
v. rare-earth oxyphosphides, such as oxyphosphides of erbium, ytterbium, dysprosium, holmium, thulium, and lutetium; or
vi. any combination of i, ii, iii, iv, and v.

The thickness of dielectric layer 104 is typically in the range of 0.5 to 5000 nm. More typically, the thickness of dielectric layer 104 is in the range of 1 to 10 nm or 10 to 100 nm.

The desired thickness of buried dielectric layer 104 scales with the gate length, L_{g}, of transistor 100. As L_{g} decreases, the desired thickness of buried dielectric layer 104 also typically decreases. For example, it is expected that future transistor technology nodes (such as the 30 nm technology node) could require a buried dielectric that is thinner than 10 nm. In some embodiments, suitable values for the thickness of buried dielectric layer 104 are within the range of approximately 5 nanometers (nm) to approximately 100 nm. A thin buried dielectric layer 104 provides several advantages over the thick buried oxide required in conventional SOI technologies. Specifically, a thin buried dielectric layer provides:
i. improved conduction of heat away from the transistor plane; or
ii. suppression of electric-field fringing effects; or
iii. suppression of short-channel effects; or
iv. improved control of random dopant fluctuations in the channel; or
v. any combination of i, ii, iii, and iv.

At operation 603, active layer 106 is formed on buried dielectric layer 104. Active layer 106 is a layer of single-phase silicon that has a thickness, tₐ, of 4 nm. Active layer 106 is epitaxially-grown on and monolithically-integrated with buried dielectric layer 104. Active layer 106 is suitable for formation of high-performance integrated circuits. Although the illustrative embodiment comprises active layer 106 that is silicon, it will be clear to those skilled in the art, after reading this specification, how to make and use alternative embodiments of the present invention wherein active layer 106 comprises:
i. silicon carbide; or
ii. germanium; or
iii. silicon-germanium; or
iv. any combination of i, ii, iii, and silicon.

In some additional embodiments, active layer 106 is a compound semiconductor, such as gallium arsenide, indium phosphide, and alloys of gallium arsenide and indium phosphide.

In similar fashion as for the buried dielectric layer, the thickness of active layer 106, tₐ, scales with the gate length, L_{g}, of transistor 100. Specifically, tₐ scales as tₐ˜L_{g}/k, where k is a unitless scaling factor, and where the value of k is within the range of 3 to 5. In some embodiments, suitable values for the thickness of active layer 106 are within the range of approximately 2 nm to approximately 50 nm. It is expected that future technology nodes (such as the 30 nm technology node) could require an active layer as thin as approximately 2 nm.

At operation 604, gate dielectric layer 114 is formed on active layer 106. In some embodiments, gate dielectric layer 114 is a layer of erbium oxide that has a thickness of 1 nm. In some embodiments, the thickness of gate dielectric layer 114 has a value within the range of approximately 0.5 nm to approximately 2 nm. As for active layer 106, the desired thickness of gate dielectric layer 114 scales with the technology node of transistor 100.

Gate dielectric layer 114 is epitaxially-grown and monolithically-integrated with active layer 106. Gate dielectric layer 114 has a single-phase crystal structure and serves the purpose of the gate dielectric in transistor 100. In some embodiments, gate dielectric 114 comprises a different material selected from the materials listed above for buried dielectric layer 104.

At operation 605, source 110 and drain 112 are formed in active layer 106. In order to form source 110 and drain 112, vias 120 are etched through gate dielectric 114 using conventional photolithography and reactive ion etching techniques. Once vias 120 are formed, source 110 and drain 112 are formed within active layer 106 by diffusion or ion implantation of a suitable dopant. In some embodiments, source 100 and drain 112 are formed by forming a silicide through the thickness of active layer 106 in the source and drain regions.

At operation 606, gate layer 116 is formed on gate dielectric layer 114. In some embodiments, gate layer 116 is a layer of silicon that has a thickness of 20 nm. Gate layer 116 is epitaxially-grown and monolithically-integrated with gate dielectric layer 114. Gate layer 116 has a single-crystal crystal structure and serves the purpose of a gate conductor in transistor 100. In order to make gate layer 116 ohmic, operation 606 continues with an implantation or diffusion of boron into gate layer 116. The boron is then activated by a high-temperature anneal. It should be noted that the high-temperature anneal required to activate the boron creates a barrier to the use of some high-K dielectric materials for gate dielectric layer 114. For example, hafnium oxide (HfO) has been widely touted as a potential gate dielectric material. Hafnium oxide, however, undergoes a phase change when subjected high temperature, such as that associated with a boron activation anneal, that substantially precludes its use in this application.

In some embodiments, gate layer 116 has a single-phase crystal structure. In some embodiments, gate layer 116 comprises a different material selected from the materials listed above for active layer 106. In some embodiments, gate layer 116 has a thickness other than 20 nm. In some embodiments of the present invention, gate layer 116, source 110, and drain 112 are doped simultaneously, thereby obviating the doping step associated with operation 605.

The single-crystal nature of gate layer 116 and gate dielectric layer 114 provide some relief for the well-known boron-diffusion problem associated with polycrystalline semiconductor gate conductors. Boron-doped polysilicon is typically used as the gate conductor in conventional CMOS transistors. The high-temperature anneal used to activate the boron in the gate conductor and make it ohmic can cause the boron atoms to rapidly diffuse along the grain boundaries of the polysilicon. The diffusion of the boron through the polysilicon can poison a thin gate dielectric, thereby killing the transistors.

The diffusivity of boron along grain boundaries is up to four orders of magnitude faster than the diffusivity of boron through single-crystal silicon. Gate dielectric layer 114 has a single-phase crystal structure; therefore, boron diffusivity in the gate dielectric is reduced. In addition, since gate layer 116 has a single-crystal crystal structure, it is substantially grain boundary-free. This further mitigates the boron-diffusion problem. In those embodiments wherein gate layer 116 has single-phase crystal structure, the boron diffusion problem is mitigated still further.

At operation 607, electrical contacts to the gate layer 116, source 110, and drain 112 are formed in well-known fashion.

As described in U.S. patent application Ser. Nos. 11/253,525 and 11/254,031, in some embodiments, one or more transitional layers are present in the layer structure of transistor 100. These transitional layers enable the growth of:
i. single-phase rare-earth dielectric material on semiconductor material; or
ii. single-crystal semiconductor material on rare-earth dielectric material; or
iii. single-phase semiconductor material on rare-earth dielectric material; or
iv. any combination of i, ii, and iii.

Crystal Structure of Rare-Earth Dielectrics

Carrier mobility in a single-crystal layer is higher than in a non-single crystal active layer. In addition, epitaxial deposition of a single-crystal active layer on a non-single-crystal buried dielectric would be difficult at best. A semiconductor-on-insulator composition in accordance with the present invention, therefore, comprises a dielectric layer 104, active layer 106, and gate dielectric layer 114, wherein each has single-crystal crystal structure, and preferably single-phase crystal structure.

Epitaxial growth of single-phase semiconductor films is well-known to those skilled in the art. But such films are typically only grown on an underlying single-crystal semiconductor. Epitaxial growth of single-phase high-K dielectrics has been, heretofore, unknown to those skilled in the art. This section, therefore, addresses important considerations in selecting and growing single-phase, high-K, rare-earth dielectrics and single-phase semiconductors on dielectric layers.

As compared to other high-K dielectric films, single-phase rare-earth dielectric layers provide several key advantages regarding their use in integrated circuit devices. Specifically, these films enable:
(i) thicker gate layers and buried dielectric layers; or
(ii) semiconductor-on-insulator structures with buried dielectric and active layers that do not exhibit a growth-thickness limitation; or
(iii) low thermionic emission of electrons across the dielectric/semiconductor interface; or
(iv) semiconductor/dielectric interfaces that exhibit a quality and defect density which rivals or surpasses that of silicon dioxide on silicon; or
(v) fabrication of semiconductor-on-insulator structures that comprise a single-crystal semiconductor layer with a thickness of 100 nanometers or less; or
(vi) any combination of i, ii, iii, iv, and v.

Dielectric films that incorporate rare-earth metals are potentially a means for providing high-K dielectric films. The term “potentially” is used because there are several important caveats to the use of rare-earth metals. Specifically, the crystal structure of rare-earth dielectrics can vary significantly. And the crystal structure, in part, makes many of these rare earth dielectrics inappropriate for use in high-performance integrated circuits. Furthermore, the crystal structure of a rare-earth dielectric can affect the quality of epitaxially-grown films that are deposited on top of the rare-earth dielectric. For example, buried dielectric 104 must have high interface quality and a single-phase morphology to enable the formation of fully-depleted electrical devices in active layer 106. Rare-earth dielectrics deposited using methods that are known in the prior art are ill-suited to the formation of fully-depleted SOI devices.

Rare-earth oxides are known to exhibit fluorite-type structures. These structures exhibit morphology differences as a function of the atomic weight of the rare-earth cation present in the oxide, among any other factors.

In particular, oxides comprising lighter rare-earths form cubic CaF₂-type crystal structure as a result of possible ionization states of +2 and/or +3 and/or +4. Oxides having this crystal structure exhibit significant net charge defect due to a multiplicity of possible oxidation states (for rare-earth oxides). This renders these rare-earth oxides inapplicable to high-performance field-effect-transistor (FET) devices. These oxides are not suitable for use in conjunction with the various embodiments of the present invention.

The layer thickness of rare-earth dielectrics is limited when grown via prior-art methods. In general, this limitation arises from lattice mismatch, internal strain, and/or electronic or structural instability of the crystal structure of the rare-earth oxides. Annealing rare-earth oxides that are formed via prior-art methods, such as hafnium oxide, in order to reduce strain results in mixed crystal phases (i.e., polycrystalline or amorphous). Layer thickness far exceeding that achieved in the prior art can be attained for rare-earth dielectrics as disclosed herein.

On the other hand, oxides formed from heavier rare-earths (e.g., RE₂O₃, etc.), exhibit a distorted CaF₂-type crystal structure which includes anion vacancies due to an ionization state of RE³⁺. The crystal structure associated with rare-earth oxides of heavier rare earths is also known as “Bixbyite.” These oxides are desirable for use as dielectric layer 104 in the compositions described herein.

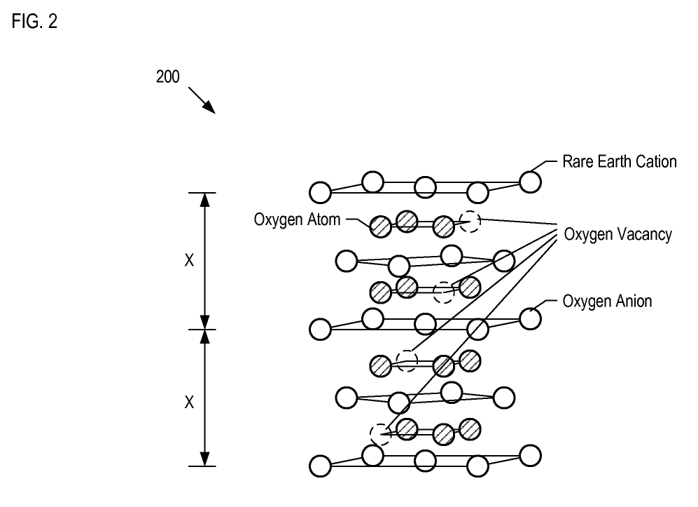

FIG. 2 depicts the crystal structure diagram of a unit cell of a rare-earth oxide having the formula RE₂O₃ in accordance with the illustrative embodiment of the present invention. Unit cell 200 is a unit cell of Er⁺³₂O₃. The crystal structure of unit cell 200 is an oxygen-vacancy-derived fluorite derivative (i.e., Bixbyite structure). Buried dielectric layer 104 and gate dielectric layer 106 comprise an assemblage of these unit cells. The erbium atoms in unit cell 200 are in a triply-ionized RE⁺³ ionization state.

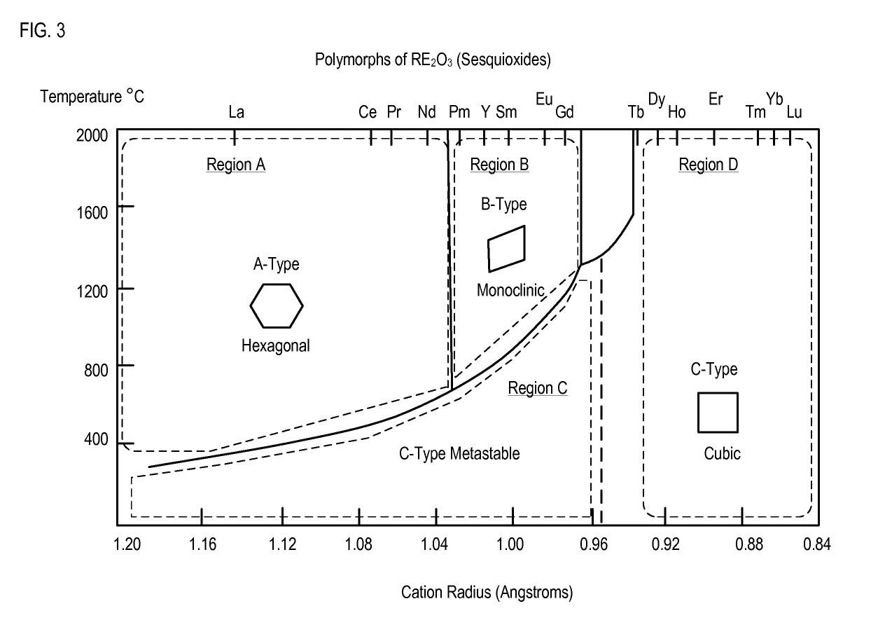

The number and position of the anion vacancies determines the crystal shape of the RE₂O₃ unit cell. The crystal shape of this cell can be engineered to provide a suitable match to the lattice constant of the underlying semiconductor substrate. Oxygen vacancies along the body diagonal and/or the face diagonal lead to a C-type cubic structure as will be discussed below and with reference to FIG. 3. For example, two anion vacancies per fluorite unit cell causes the unit cell of Er³⁺₂O₃ to increase to nearly twice the unit cell size of Si. This, in turn, enables low-strain, single-phase Er³⁺₂O₃ to be epitaxially grown directly on a silicon substrate.

Furthermore, the number and position of the anion vacancies can be engineered to induce a desired strain (tensile or compressive) in the dielectric layer and/or overgrown layers. For example, in some embodiments, strain in the semiconductor layer is desired in order to affect carrier mobility.

Each fluorite unit cell has two oxygen vacancies, which lie along the body diagonal as shown. The presence of these two oxygen vacancies causes the Er³⁺₂O₃ unit cell to double in size, thereby doubling its lattice constant, which provides a suitable match to the lattice constant of <100> silicon.

In some alternative embodiments, oxygen vacancies lie at the ends of the face diagonal. In some other alternative embodiments, oxygen vacancies are distributed between the ends of the face diagonal and the body diagonal.

Certain factors must be addressed to produce a composition that includes a dielectric layer comprising a single-phase rare-earth dielectric. In particular:
(1) rare-earth metals having an atomic number of 65 or less, such as cerium, promethium, or lanthanum, form cations with radii larger than 0.93 angstroms, which is unsuitable for use in embodiments of the present invention; and
(2) the growth of a polar rare-earth oxide (which comprises cations and anions) on a non-polar substrate (such as silicon or germanium) tends toward multi-domain growth due to the lack of an energetically-favorable bonding site for one of either the cations or anions of the rare-earth dielectric.

The uniformity and stability of the crystal structure of a rare-earth oxide is dependent upon the radius of the included rare-earth cation. FIG. 3 depicts a chart of the polymorphs of rare-earth oxides versus temperature and as a function of cation radius.

Regions A through C are regions of temperature and cation radius wherein the crystal structure of the polymorphs of rare-earth oxides are unstable and are not limited to a single type over all temperatures. Therefore, rare-earth oxides formed using these rare-earth elements will exhibit polycrystalline or multi-domain crystal structure. Such oxides are undesirable for use in conjunction with the compositions that are disclosed herein.

For example, the crystal structure of a rare-earth oxide comprising lanthanum, which has a cation radius of 1.14, changes as the temperature of the crystal reduces from growth temperature to room temperature. The crystal structure of such a lanthanum-oxide will change from an A-type hexagonal structure above 400° C. to a C-type metastable structure below 400° C.

Region D is the only region wherein the rare-earth oxide polymorphs are stable over the temperature range from room temperature to 2000° C. The rare-earth oxide polymorphs that exist in region C include sesquioxides that have a cation radius less than 0.93. The rare-earth elements that have cation radii less than 0.93 include dysprosium, holmium, erbium, thulium, ytterbium, and lutetium. These rare-earth elements are also characterized by an atomic number greater than or equal to 66. These rare-earth metals, therefore, will form a stable oxygen-vacancy-derived fluorite crystal structure (i.e., Bixbyite) that exhibits single-phase structure. Consequently, rare-earth metals that are suitable for use in conjunction with the illustrative embodiment include dysprosium, holmium, erbium, thulium, ytterbium, and lutetium.

Rare-earth dielectrics are typically polar. Growing polar rear-earth dielectrics on a non-polar substrate (such as silicon or germanium) usually results in multi-domain growth, which is unacceptable for use in conjunction with the present invention. In accordance with the present invention, specific techniques are employed to ensure single-phase growth of a polar layer on a non-polar surface and/or a non-polar layer on a polar surface.

In order to form a semiconductor-on-insulator structure that is suitable for high-performance FET devices, active layer 106 should have a single-phase crystal structure. The optimal deposition surface for producing a single-phase active layer (e.g., silicon, germanium, silicon-carbide, or silicon-germanium) via epitaxy is non-polar, since silicon and germanium are non-polar crystals. But most rare-earth dielectrics typically comprise polar crystals. In accordance with the present invention, specific techniques are employed to ensure epitaxial growth of single-phase non-polar semiconductors on polar surfaces.

The methods employable for growing non-polar semiconductors on polar surfaces and single-phase growth of polar dielectrics on non-polar surfaces are disclosed in detail in U.S. patent application Ser. Nos. 11/253,525 and 11/254,031.

An advantage afforded by the present invention is the option to include a conductive layer in a semiconductor-on-insulator structure. A buried conductive layer is particularly desirable in many wireless/RF, mixed analog/digital signal, and mixed bipolar/CMOS applications.

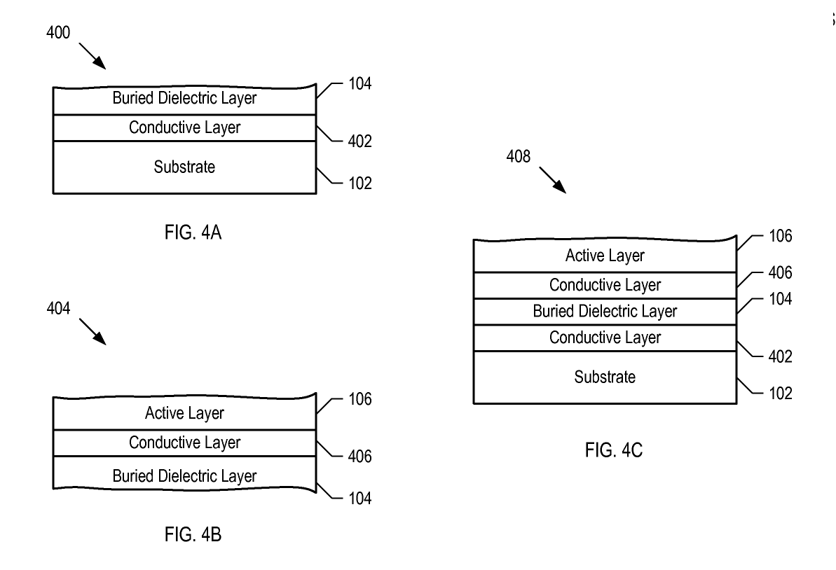

FIG. 4A depicts a cross-sectional view of a portion of a semiconductor-on-insulator substrate comprising a buried ground plane in accordance with an alternative embodiment of the present invention. Partial layer structure 400 comprises substrate 102, conductive layer 402, and buried dielectric layer 104. Conductive layer 402 acts as a buried ground plane for circuitry formed in layers above the portion of the substrate shown.

Conductive layer 402 is a single-crystal rare-earth silicide having a thickness of approximately 10 nm. In some embodiments, conductive layer 402 has a thickness within the range of one monolayer to approximately 25 nm. One method for forming conductive layer 402 is an epitaxial deposition of a layer of rare-earth metal directly on silicon substrate 102. This deposition is subsequently followed by a thermal anneal. During the thermal anneal, the rare-earth metal reacts with the silicon atoms at the top surface of substrate 102 and forms a layer of electrically-conductive rare-earth silicide.

FIG. 4B depicts a cross-sectional view of a portion of a semiconductor-on-insulator substrate comprising a buried conductor in accordance with an alternative embodiment of the present invention. Partial layer structure 404 comprises buried dielectric layer 104, conductive layer 406, and active layer 106.

Conductive layer 406 is a single-crystal rare-earth silicide having a thickness of approximately 10 nm. In some embodiments, conductive layer 406 has a thickness within the range of one monolayer to approximately 25 nm. Conductive layer 406 is formed by (1) epitaxially-depositing a layer of rare-earth metal on buried dielectric layer 104; (2) epitaxially depositing a single-phase active layer comprising silicon; and (3) annealing the layers to cause the rare-earth metal to react with silicon atoms at the bottom surface of active layer 106 to form an electrically-conductive silicide layer.

FIG. 4C depicts a cross-sectional view of a portion of a semiconductor-on-insulator substrate comprising a buried conductor layer and a buried ground plane in accordance with an alternative embodiment of the present invention. Partial layer structure 408 comprises substrate 102, conductive layer 402, buried dielectric layer 104, conductive layer 406, and active layer 106.

Conductive layer 402 acts as a buried ground plane for circuitry formed above the portion of the substrate shown.

Conductive layer 406 acts as a buried conductor for active layer 106.

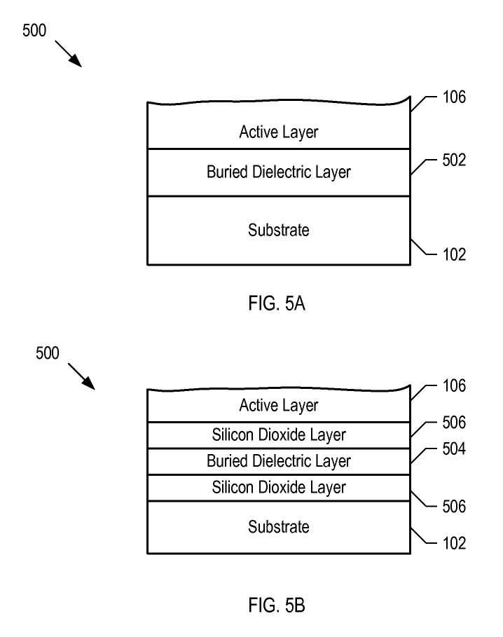

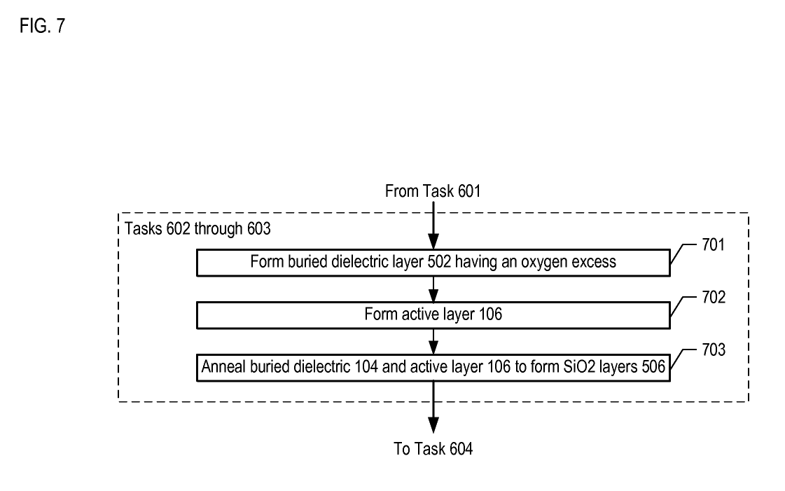

In some applications, it is desirable to form a buried dielectric layer that comprises silicon dioxide interface layers on both top and bottom surfaces, while still exhibiting a single-phase crystal structure. As compared to a comparable simple rare-earth dielectric layer, such a composite structure can provide a lower dielectric constant and a larger effective electrical band-gap. With reference to FIGS. 5 and 7, a composite buried dielectric layer is described in conjunction with method 700, which is suitable for its fabrication.

FIG. 5A depicts a cross-sectional view of a portion of a semiconductor-on-insulator substrate comprising a buried dielectric layer having an oxygen concentration gradient, before anneal, in accordance with an alternative embodiment of the present invention. Partial layer structure 500 comprises substrate 102, buried dielectric layer 502, and active layer 106.

At operation 701, buried dielectric layer 502 is epitaxially deposited on substrate 102 in an atomic layer epitaxy chamber having an elevated oxygen background concentration (i.e., a high oxygen partial pressure). As a result, buried dielectric layer 502 is a single-phase rare-earth oxide that, prior to being thermally annealed, has an oxygen concentration excess. The oxygen concentration in buried dielectric layer is kept sufficiently low to enable the epitaxial deposition of active layer 106 with the same crystal orientation as substrate 102. In some embodiments, an oxygen concentration profile, such as a linear gradient, cubic function, or the like, is formed within buried dielectric layer 502. At operation 702, active layer 106 is epitaxially-deposited on buried dielectric layer 502.

FIG. 5B depicts a cross-sectional view of a portion of a semiconductor-on-insulator substrate comprising a buried dielectric layer having a reduced high-K dielectric constant, after anneal, in accordance with an alternative embodiment of the present invention. After thermal anneal, partial layer structure 500 comprises substrate 102, buried dielectric layer 504, and silicon dioxide layers 506.

At operation 703, transistor 100 is annealed at a temperature suitable to cause excess oxygen atoms in buried dielectric layer 504 to react with silicon atoms in substrate 102 and active layer 106. This reaction consumes the excess oxygen atoms and produces silicon dioxide layers 508. The production of silicon dioxide layers 508 is self-terminating at a thickness determined by the oxygen excess. After operation 703, the crystal structure of active layer 106 remains substantially perfect.

It is to be understood that the above-described embodiments are merely illustrative of the present invention and that many variations of the above-described embodiments can be devised by those skilled in the art without departing from the scope of the invention. For example, in this Specification, numerous specific details are provided in order to provide a thorough description and understanding of the illustrative embodiments of the present invention. Those skilled in the art will recognize, however, that the invention can be practiced without one or more of those details, or with other methods, materials, components, etc.

Furthermore, in some instances, well-known structures, materials, or operations are not shown or described in detail to avoid obscuring aspects of the illustrative embodiments. It is understood that the various embodiments shown in the Figures are illustrative, and are not necessarily drawn to scale. Reference throughout the specification to “one embodiment” or “an embodiment” or “some embodiments” means that a particular feature, structure, material, or characteristic described in connection with the embodiment(s) is included in at least one embodiment of the present invention, but not necessarily all embodiments. Consequently, the appearances of the phrase “in one embodiment,” “in an embodiment,” or “in some embodiments” in various places throughout the Specification are not necessarily all referring to the same embodiment. Furthermore, the particular features, structures, materials, or characteristics can be combined in any suitable manner in one or more embodiments. It is therefore intended that such variations be included within the scope of the following claims and their equivalents.

What is claimed is:

1. A planar field-effect transistor structure comprising:
a first dielectric layer, wherein said first dielectric layer interposes a gate layer and a first semiconductor layer that comprises a first semiconductor, and wherein said first dielectric layer comprises a first rare-earth metal, and further wherein said first dielectric layer has a substantially single-phase crystal structure; and
said gate layer disposed on said first dielectric layer, wherein said gate layer comprises a second semiconductor, and wherein said second semiconductor has a substantially single-crystal crystal structure.

2. The transistor structure of claim 1 further comprising:
said first semiconductor layer disposed on a second dielectric layer, wherein said active layer comprises a first semiconductor, and wherein said first semiconductor has a substantially single-phase crystal structure; and
said second dielectric layer, wherein said second dielectric layer is disposed on a substrate, and wherein said second dielectric layer comprises a second rare-earth metal, and further wherein said second dielectric layer has a substantially single-phase crystal structure.

3. The transistor structure of claim 2 further comprising a conductor layer, wherein said conductor layer interposes said second dielectric and said active layer.

4. The transistor structure of claim 2 further comprising a conductor layer, wherein said conductor layer interposes said second dielectric and said substrate.

5. The transistor structure of claim 2 further comprising:
a source region within said first semiconductor layer, wherein said source region comprises a silicide; and
a drain region within said first semiconductor layer, wherein said drain region comprises a silicide.

6. The transistor structure of claim 2 further comprising:
a source region within said first semiconductor layer; and
a drain region within said first semiconductor layer;
wherein said source region and said drain region are doped with a dopant that is one of a p-type dopant and an n-type dopant.

7. The transistor structure of claim 2 wherein:
said first semiconductor is individually selected from the group consisting of silicon, germanium, and silicon-germanium; and
said second semiconductor is individually selected from the group consisting of silicon, germanium, and silicon-germanium.

8. The transistor structure of claim 1 wherein said second semiconductor has a substantially single-phase crystal structure.

9. The transistor structure of claim 1 wherein said first dielectric layer comprises at least one of a rare-earth oxide, a rare-earth oxynitride, a rare-earth nitride, a rare-earth oxyphosphide, and a rare-earth phosphide.

10. The transistor structure of claim 1 wherein said first rare-earth metal forms a cation having a radius less than 0.93 angstroms.

11. The transistor structure of claim 1 wherein said first rare-earth metal has an atomic number greater than or equal to 66.

12. The transistor structure of claim 1 wherein said first rare-earth metal is in a RE³⁺ionization state.

13. The transistor structure of claim 1 wherein said first dielectric layer has an anion-vacancy-derived fluorite-crystal crystal structure.

14. A transistor structure comprising:
a buried dielectric layer, wherein said buried dielectric layer comprises a rare-earth metal, and wherein said buried dielectric layer has a substantially single-phase crystal structure;
a first semiconductor layer disposed on said buried dielectric layer, wherein said first semiconductor layer has a substantially single-phase crystal structure;
a gate dielectric layer, wherein said gate dielectric layer is disposed on said first semiconductor layer, and wherein said gate dielectric layer comprises a rare-earth metal, and further wherein said gate dielectric layer has a substantially single-phase crystal structure; and
a gate conductor disposed on said gate dielectric layer, wherein said gate conductor comprises a second semiconductor having a substantially single-crystal crystal structure.

15. The transistor structure of claim 14 wherein said first semiconductor layer further comprises a channel region, a source region, and a drain region, wherein said channel region interposes said source region and said drain region, and wherein said source region and said drain region are doped with a dopant that is one of a p-type dopant and an n-type dopant.

16. The transistor structure of claim 14 wherein said first semiconductor layer further comprises a channel region, a source region, and a drain region, wherein said channel region interposes said source region and said drain region, and wherein said source region and said drain region each comprise a silicide that extends substantially through the thickness of said first semiconductor layer.

17. The transistor structure of claim 14 wherein said buried dielectric layer has a thickness within the range of 5 nm to 100 nm.

18. The transistor structure of claim 14 wherein said buried dielectric layer has a thickness within the range of 18 nm to 44 nm.

19. The transistor structure of claim 14 wherein said buried dielectric layer has a thickness within the range of 5 nm to 28 nm.

20. The transistor structure of claim 14 wherein said gate dielectric layer has a thickness within the range of 0.5 nm to 10 nm.

21. The transistor structure of claim 14 wherein said gate dielectric layer has a thickness within the range of 0.5 nm to 2 nm.

22. The transistor structure of claim 14 wherein said first semiconductor layer comprises a material selected from the group consisting of silicon, germanium, and silicon-germanium.

23. The transistor structure of claim 14 wherein said first semiconductor layer has a thickness within the range of 2 nm to 50 nm.

24. The transistor structure of claim 14 wherein said first semiconductor layer has a thickness within the range of 2 nm to 20 nm.

25. The transistor structure of claim 14 wherein said first semiconductor layer has a thickness within the range of 2 nm to 6 nm.

26. The transistor structure of claim 14 wherein said gate dielectric comprises at least one of a rare-earth oxide, a rare-earth oxynitride, a rare-earth nitride, and a rare-earth oxyphosphide.

27. The transistor structure of claim 14 wherein said rare-earth metal forms a cation having a radius less than 0.93 angstroms.

28. The transistor structure of claim 14 wherein said rare-earth metal has an atomic number greater than or equal to 66.

29. The transistor structure of claim 14 wherein the crystal structure of said first dielectric layer is that of an oxygen-vacancy-derived fluorite crystal.

30. A method comprising:
forming a first dielectric layer, wherein said first dielectric layer is disposed on a first surface of a substrate, and wherein said first dielectric layer comprises a rare-earth metal, and further wherein said first dielectric layer has a substantially single-phase crystal structure;
forming a first semiconductor layer disposed on said first dielectric layer, wherein said first semiconductor layer has a substantially single-phase crystal structure, and wherein said first semiconductor layer is doped with a first dopant that is one of a p-type dopant and an n-type dopant;
forming a second dielectric layer disposed on said first semiconductor layer, wherein second dielectric layer has a substantially single-phase crystal structure; and
forming a second semiconductor layer disposed on said second dielectric layer, wherein said second dielectric layer comprises a rare-earth metal, and wherein said second semiconductor layer has a substantially single-crystal crystal structure.

31. The method of claim 30 further comprising:
forming a first electrical contact and a second electrical contact to said first semiconductor layer; and
forming a third electrical contact to said second semiconductor layer.

32. The method of claim 30 further comprising forming a source region and a drain region in said first semiconductor layer by doping said source region and said drain region with a second dopant, wherein said second dopant is of opposite type from said first dopant.

33. The method of claim 30 further comprising forming a source region and a drain region in said first semiconductor layer by forming a silicide in said source region and said drain region.

34. The method of claim 30 further comprising providing said first surface such that said first surface is supportive of epitaxial growth of a rare-earth dielectric having a substantially single-phase crystal structure.

35. The method of claim 30 further comprising mis-orienting said first surface from a major crystalline orientation by an angle that has a value within the range of 0.1 to 20 degrees, wherein said major crystalline orientation is selected from the group consisting of <111>, <100>, and <011>.

36. The method of claim 30 further comprising providing said substrate, wherein said substrate comprises a silicon wafer, and wherein first surface has a crystal orientation that is miscut from a major crystalline orientation by an angle that has a value within the range of 0.1 to 20 degrees, and further wherein said major crystalline orientation is selected from the group consisting of <111>, <100>, and <011>.

37. The method of claim 30 wherein said first dielectric layer is formed with an oxygen excess.

38. The method of claim 37 further comprising heating said first dielectric layer to induce said oxygen excess to form a silicon dioxide layer.

39. The method of claim 30 further comprising forming a first conductive layer, wherein said first conductive layer interposes said first surface and said first dielectric layer.

40. The method of claim 30 further comprising forming a first conductive layer, wherein said first conductive layer interposes said first dielectric layer and said first semiconductor layer.
